(19) United States
(12) Patent Application Publication
(10) Pub. No.: US 2005/0281010 A1
(43) Pub. Date: Dec. 22, 2005

(54) Contact pad arrangement for integrated SD/MMC system

(75) Inventors: Kuang-Yu Wang, Saratoga, CA (US); Jim Ni, San Jose, CA (US); Sun-Teck See, San Jose, CA (US)

Correspondence Address: BEVER HOFFMAN & HARMS, LLP;TRI-VALLEY OFFICE, 1432 CONCANNON BLVD., BLDG. G, LIVERMORE, CA, 94550, US

(73) Assignee: Super Talent Electronics, Inc., San Jose, CA (US)

(21) Appl. No.: 10/871,133

(22) Filed: Jun. 18, 2004

(51) Int. Cl. H05K 7/06; H05K 5/04

(52) U.S. Cl. 361/752; 361/777; 361/756

(57) ABSTRACT

A memory card having thirteen contact pads arranged on a PCB in a manner that supports an integrated SD/MMC system. Eight contact pads form a front row, four contact pads form a second row behind the front row, and a thirteenth contact pad is located between the front and back rows adjacent to a chamfer formed on the PCB. An L-shaped gap region is provided between the first and second rows, and between the second row and side edge of the PCB. An optional alignment notch is defined along the side edge adjacent the second row. An optional alignment hole is defined between adjacent contact pads of the second row that receives an alignment pin passing between two covers of a two-part housing. The memory card electronics are compatible with either the MMC or SD protocols, and the housing is consistent with either the MMC or SD mechanical form factors.

### BACKGROUND OF THE INVENTION

1. Field of the Invention

This invention relates to removable memory cards, and more particularly to removable memory cards for dual-protocol systems.

2. Related Art

Flash-memory cards are widely used for storing digital pictures captured by digital cameras. One useful format is the Secure-Digital (SD) format, which is an extension of the earlier MultiMediaCard (MMC) format. Such memory cards are also useful as add-on memory cards for other devices, such as portable music players, personal digital assistants (PDAs), and even notebook computers. SD cards are hot-swappable, allowing the user to easily insert and remove SD cards without rebooting or cycling power. Since the SD cards are small, durable, and removable, data files can easily be transported among electronic devices by being copied to an SD card. SD cards are not limited to flash-memory cards, but other applications such as communications transceivers can be implemented as SD cards.

SD and MMC are complementary card interfaces, and are sometimes lumped together and referred to as SD/MMC cards. Both SD and MMC cards are thin and the area they occupy is about that of a large postage stamp. Older “7-pad” MMC cards have 7 metal connector pads, while newer “9-pad” MMC cards and SD cards have nine connector pads. MMC cards can fit in SD slots, but SD cards, which are packaged in about 50% thicker housings, cannot fit in MMC slots. In systems that accept either SD or MMC cards, the host socket must be sized to accept both card types, and also must have an operating system capable of determining which type of card is inserted into its socket, and capable of transmitting the necessary communication protocol needed to communicate with the inserted card. When a 7-pad MMC card is inserted, only seven contact pins of the socket are used for communication, while the additional two socket pins are used when a 9-pad MMC or SD card are detected in the slot.

The 9-pad SD interface currently supports a top transfer rate of 100 Mb/s, which is sufficient for many applications. However, some applications such as storage and transport of full-motion video could benefit from higher transfer rates. One limitation to the 9-pad form factor is that data is transferred in a parallel x4-bit manner (i.e., four bits per transmission cycle).

One method to improve transmission speeds for SD and MMC cards is to facilitate x8-bit data transmission by increasing the number of contact pads to thirteen. MMC recently announced its Specification Version 4.0, which introduced a two-row, thirteen contact pad arrangement and associated electronics. While the 13-pad arrangement introduced in the MMC 4.0 specification is generally backward compatible to earlier MMC and SD cards, the arrangement calls out enlarged contact areas that preclude the formation of a write protect switch utilized in SD cards. Accordingly, the MMC Specification Version 4.0 cannot be used to produce memory cards for systems that communicate with both SD and MMC card form factors.

What is needed is printed circuit board (PCB) that can be used to produce both MMC and SD memory cards for an integrated SD/MMC system. In particular, what is needed is a PCB having a thirteen contact pad arrangement that is both backward compatible with existing 7-pad and 9-pad MMC and SD cards, and also facilitates the write protect switch utilized by the SD mechanical form factor.

### SUMMARY OF THE INVENTION

The present invention is directed to printed circuit boards (PCBs) having contact pads arranged in a novel 13-pad configuration that facilitates the fabrication of memory cards meeting both the Secure-Digital (SD) and MultiMediaCard (MMC) form factors, thereby facilitating an integrated SD/MMC system in which a given PCB may be used to produce a memory card based on either the SD or the MMC electronic protocols. The present invention is also directed to 13-pad memory cards that are fabricated using the novel 13-pad configuration, along with various alignment features that greatly facilitate accurate positioning of the contact pads during assembly and use.

According to a disclosed embodiment, the thirteen contact pads are formed on a substantially rectangular PCB having a chamfer formed between the front edge and a first (relatively short) side edge, with the front edge forming a substantially right angle with the second (relatively long) side edge. Twelve of the thirteen contact pads are generally grouped in two rows, with a first group of eight pads defining a first row formed along the front edge, and a second group of four pads forming a second row located behind the back edges of the first row contact pads. A thirteenth contact pad array is located along the chamfer and is offset between the first and second rows. The front (first) row of contact pads and a somewhat offset thirteenth contact pad are backward compatible with 7-pad and 9-pad MMC and SD form factors.

According to an aspect of the present invention, an L-shaped gap region is provided between the first and second rows of contact pads, and between the second row of contact pads and the relatively long side edge of the PCB (i.e., such that the upright portion of the “L” extends between the first and second rows, and the lower horizontal portion of the “L” extends behind the end contact pad of the first row along the longer side edge of the PCB). The region corresponding to the lower horizontal portion of the L-shaped gap region facilitates dual-protocol systems in that the “switch” gap region located behind the first row along the longer side edge of the PCB is consistent with the write protect switch detector needed to support the SD protocol.

According to another aspect of the present invention, the thirteenth contact pad (i.e. the contact pad located behind the chamfer edge of the PCB) is substantially rectangular, has a front end aligned with the first row and a back end aligned with the second row, thereby providing a reduced contact pad area that provides additional PCB surface area for other purposes.

According to another aspect of the present invention, an alignment notch is defined along the longer side edge behind the first row of contact pads to facilitate both precise position of the PCBA in the housing, and also to facilitate the addition of a write protect switch on the housing. In one embodiment, the alignment notch includes a front edge located between the back end of the first (front) contact pad row and the front end of second (back) contact pad row, and back notch edge that is located behind the second contact pad row. The alignment notch has a side edge that is substantially parallel to the longer side edge of the PCB, and the notch is sufficiently deep that at least a portion of the rightmost contact pad of the first row is located to the right of a line coincident with the side edge of the notch. In one embodiment, the side notch edge is aligned with a penultimate (seventh) contact pad of the first row. One or more additional alignment notches may be provided along either side edge of the PCB.

According to another aspect of the present invention, the four contact pads of the second row are arranged in two sub-groups that are spaced apart by a relatively wide central gap, and the PCB defines an alignment hole located in this central gap that passes entirely through the PCB material. The alignment hole facilitates the secure connection of upper and lower covers of a housing subsequently attached over the PCB (i.e., by way of an alignment pin passing through the alignment hole between the upper and lower housing covers).

According to another aspect of the present invention, a PCB assembly (PCBA) includes a controller integrated circuit (IC) and memory IC mounted on the 13-pad PCB such that the controller IC and memory IC are electrically connected to at least one contact pad of the contact pad array. In one embodiment, the controller IC and memory IC are fabricated to operate according to the established MMC protocol, and this PCBA is mounted in a two-part housing consistent with the SD mechanical form factor. According to one exemplary embodiment, the MMC-based PCBA is mounted in a molded housing consistent with the MMC mechanical form factor. In another embodiment, the controller IC and memory IC are fabricated to operate according to the established SD protocol.

The invention will be more fully understood in view of the following description of the exemplary embodiments and the drawings thereof.

### BRIEF DESCRIPTION OF THE DRAWINGS

FIGS. 1(A) and 1(B) are top plan and end elevation views showing a 13-pad PCBA according to an embodiment of the present invention.

FIG. 2 is a top plan view showing a 13-pad PCBA including an alignment notch according to another embodiment of the present invention.

FIG. 3 is a top plan view showing a 13-pad PCBA including an alignment hole according to another embodiment of the present invention.

FIG. 4 is a top plan view showing a shortened 13-pad PCBA according to another embodiment of the present invention.

FIG. 5 is an exploded perspective view showing a memory card including a two-part housing and the PCBA of FIG. 2 according to another embodiment of the present invention.

FIG. 6 is an assembled perspective view showing the memory card of FIG. 5.

FIG. 7 is an exploded perspective view showing a memory card including a two-part housing and the PCBA of FIG. 3 according to another embodiment of the present invention.

FIGS. 8(A) and 8(B) are partial cross-sectional side views showing an alignment structure of the memory card of FIG. 7 according to alternative embodiments.

FIGS. 9(A), 9(B), and 9(C) are top, bottom, and side views, respectively, showing a memory card incorporating the PCBA of FIG. 1 and a molded casing in accordance with another exemplary embodiment of the present invention.

FIG. 10 is a cross-sectional end view showing a portion of the memory card of FIGS. 9(A) to 9(C).

FIGS. 11(A) and 11(B) are cross-sectional side views showing alternative molded casing structures associated with the memory card of FIGS. 9(A) to 9(C).

### DETAILED DESCRIPTION

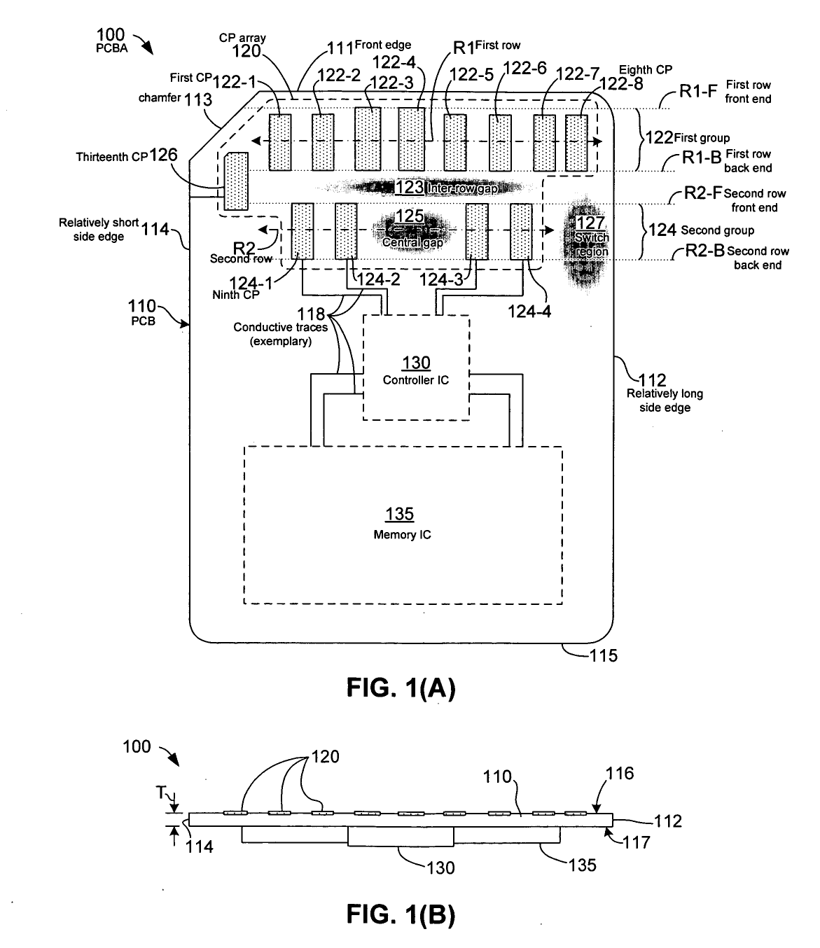

FIGS. 1(A) and 1(B) are top plan and end elevation views showing a printed circuit board assembly (PCBA) 100 for a 13-pad memory card according to an embodiment of the present invention. PCBA 100 generally includes a printed circuit board (PCB) 110 having a contact pad array 120 mounted on a first (e.g., upper) surface thereof, and one or more integrated circuits (ICs) 130 and 135 mounted on a second (e.g., lower) surface thereof. PCB 110 is formed in accordance with known PCB manufacturing techniques such that the contact pads of array 120 and ICs 130 and 135 (as well as other circuit components, which are omitted for brevity) are electrically interconnected by a predefined network of conductive traces 118 (only a few of which are shown for illustrative purposes).

PCB 110 is a substantially rectangular, flat substrate including multiple layers of conductive traces 118 and other conducting structures sandwiched between multiple layers of an insulating material (e.g., FR4) and adhesive. PCB 110 includes a front edge 111, a relatively long side edge 112, a relatively short side edge 114 located opposite to relatively long side edge 112, and a back edge 115. A chamfer (angled) edge 113 extends at approximately 45° between front edge 111 and shorter side edge 114. In one embodiment, PCB 110 has a length (i.e., measured from front edge 111 to back edge 115) designed to fit in a housing with 32 mm in length, a width (measured from longer side edge 112 to shorter side edge 114) designed to fit in the same housing with 24 mm in width, and a thickness T (measured from lower surface 116 to upper surface 117, as shown in FIG. 1(B)) of approximately 0.3 mm.

Referring to FIG. 1(A), contact pad array 120 consists of multiple rows of metal (e.g., copper) contact pads that are formed on lower surface 116 of PCB 110 according to known techniques. In particular, contact pad array 120 includes thirteen contact pads designated as a first contact pad group 122, which includes eight substantially rectangular contact pads 122-1 through 122-8 arranged to form a first row R1 that is parallel to front edge 111, a second group 124, which includes four substantially rectangular contact pads 124-1 through 124-4 arranged to form a second row R2 that is parallel to first row R1, and a thirteenth contact pad 126 that spans the first and second rows and is located adjacent to chamfer edge 113. First group 122 includes a first contact pad 122-1 that is located adjacent to an intersection of front edge 111 and chamfer edge 113, an eighth contact pad 122-8 that is located adjacent to longer side edge 112, and six intermediate contact pads 122-2, 122-3, 122-4, 122-5, 122-6 and 122-7 respectively arranged between first contact pad 122-1 and eighth contact pad 122-8. In one embodiment, contact pads 122-1, 122-2 and 122-5 through 122-8 define rectangular regions (elongated bodies) that are approximately 5 mm in length and 1.3 mm in width, and contact pads 122-3 and 122-4 define slightly larger regions that are approximately 5.3 mm in length and approximately 1.7 mm in width. The majority of pads 124-1, 124-2, 124-3 and 124-4 should be able to fit into the space defined laterally by the edges between pads 122-1 and 122-2, 122-2 and 122-3, 122-5 and 122-6, and 122-6 and 122-7, respectively. The front ends of contact pads 122-1 through 122-8 (i.e., the ends closest to front edge 111) define a front end R1-F of first row R1, and the back ends of contact pads 122-1 through 122-8 (i.e., the ends furthest from front edge 111) define a back end R1-B of first row R1. Similarly, contact pads 124-1 through 124-4 of second row R2 define rectangular regions that are approximately 5 mm in length and 1.3 mm in width, the front ends of contact pads 124-1 through 124-4 define a front end R2-F of second row R2, and the back ends of contact pads 124-1 through 124-4 define a back end R2-B of second row R2. Respective spacings between adjacent contact pads of the first and second groups are approximately 1.5 mm (on average). Note that (ninth) contact pads 124-1 and (tenth) contact pad 124-2 form a first subgroup of second row R2, and (eleventh) contact pad 124-3 and (twelfth) contact pad 124-4 form a second subgroup of second row R2 that is spaced from the first subgroup by a relatively wide central gap 125 (i.e., approximately 6.6 mm). Note that the longitudinal direction of all of the contact pads of array 120 is substantially perpendicular to front edge 111 of PCB 110.

As set forth in the following paragraphs, the PCB form factor and arrangement of contact pads of array 120 provide a substantial improvement over existing memory card specifications because array 120 facilitates the production of MMC cards that can be utilized in sockets constructed to receive SD memory cards, thereby facilitating electronic systems that accept and read both MMC and SD memory cards. In addition, array 120 facilitates the production of 13-pad MMC memory cards that utilize existing SD write protection apparatus to protect information written thereon, which is not possible using existing 13-pad MMC card form factors.

MultiMediaCard (MMC) Association (www.mmca.org) announced Specification Version 4.0 in February 2004 including a 13-pad arrangement. MMC Specification Version 4.0 features wider bus-width (x1 bit, x4 bit, or x8 bit), higher clock frequency with up to 20× faster transfer speed, and dual voltage operation enabling applications at lower power consumption by small mobile devices. Like PCBA 100, a memory card complying with MMC Specification version 4.0 includes thirteen metal contact pads (designated C1 through C13) formed in two rows on a PCB (substrate). The PCB of the MMC 4.0 specification is essentially identical to the form factor (i.e., length, width, thickness) described above with respect to PCB 110. The location of the contact pads according to the MMC 4.0 specification allows the card remains compatible with the older version MMC card standard (3.X) while providing additional contact pads in the second row to facilitate x8 bit transmissions. For example, the 13 metal contact pads of the MMC 4.0 specification allow the memory card to communicate with a host device in “8 bit” set up for I/O transmission.

The specific positioning, shape and size of the thirteen contact pads associated with MMC Specification Version 4.0 is similar to the contact pad arrangement of array 120, with two notable differences. The placement, size, and spacing of contact pads 122-1 through 122-7 and 124-1 through 124-4 of array 120 (shown in FIG. 1(A)) are essentially identical to corresponding contact pads of the Specification Version 4.0 (i.e., contact pads C1-C7 and C10-C13). In addition, eighth contact pad 122-8 and thirteenth contact pad 126 of array 120 correspond to portions of contact pads C8 and C9, respectively, of the MMC Specification Version 4.0 arrangement. However, contact pads C8 and C9 include extended body sections that are not utilized in contact pads 122-8 and 126 of array 120. In particular, a leading section of contact pad C8 (i.e., the portion generally aligned with the first contact pad row) corresponds to eighth contact pad 122-8, but contact pad C8 also includes a rear section that extends from the back end of the first (front) row to the back end of the second row. In addition, a leading section of contact pad C9 corresponds to thirteenth contact pad 126, but contact pad C9 also includes a rear section that extends from the back end of the leading section to the back end of the second row.

As set forth in the following paragraphs, the PCB form factor and arrangement of contact pads of array 120 provide a substantial improvement over existing memory card specifications because array 120 facilitates the production of both SD and MMC memory cards, thereby facilitating electronic systems that accept and read both MMC and SD memory cards. In addition, array 120 facilitates the production of 13-pad MMC memory cards that utilize existing SD write protection apparatus to protect information written thereon, which is not possible using existing 13-pad MMC card form factors.

The present inventors have determined that only the leading portion of contact pads C8 and C9 of the MMC Specification Version 4.0 arrangement are necessary and desirable to facilitate access using a socket that is configured to access both MMC and SD memory cards. That is, for a system to accept and read both SD and MMC memory cards, the system would require a socket that (a) has a sufficiently large opening to accept the thicker SD form factor, (b) have contact pins capable of electrically connecting to the various pin arrangements provided on the SD and MMC memory cards, and (c) have a write protect detector positioned to detect the position of a write protect switch located on the longer side edge of standard SD housing. Taking advantage of requirement (a) (i.e., a socket large enough to accept SD memory cards), the present inventors propose an MMC memory card (described below) that is packaged in a housing based on the thicker SD form factor, although the thinner MMC form factor would certainly fit within such a socket. However, in meeting requirements (b) and (c), the present inventors have determined that the rear portions of contact pads C8 and C9 are undesirable because these portions are not consistent with the earlier form factors, because these portions unnecessarily take up valuable PCB surface area, and because the rear portion of contact pad C8 precludes the provision of a write protect switch. That is, only the leading (front) portions of contact pads C8 and C9 are consistent with corresponding contact pads of the MMC 9-pin form factor and the SD 9-pin form factor, so socket contact pins that access the rear portions would be either be incompatible with these previous form factors, or redundant (if provided in addition to pins that contact the front portions of these contact pads). Further, because the rear portion of contact pad C8 of MMC Specification Version 4.0 coincides with the position of the write protect switch detection apparatus used in SD systems, the inventors note that producing a socket that both supports write protect switch detection and includes a pin positioned to contact the rear section of contact pad C8 would be difficult and impractical. Accordingly, the present inventors determined that eliminating the rear section of contact pads C8 and C9 greatly facilitates the formation of a system that supports both SD and MMC memory cards. Thus, the novel contact pad arrangement of array 120 provides several benefits over previously established 13-pin contact pad arrangements.

Referring again to FIG. 1(A), according to a first aspect of the present invention, contact pad array 120 is characterized in that the eight contact pads 122-1 through 122-8 of the first group 122 are separated from the four contact pads 124-1 through 124-4 of second group 124 to by an elongated gap 123 (generally indicated by shaded region) that extends between the back ends of contact pads 122-1 through 122-8 and the front ends of contact pads 124-1 through 124-4. In particular, the back ends of contact pads 122-1 through 122-8 define back end (first straight) line R1-B of first row R1, and the front ends of contact pads 124-1 through 124-4 define front end (second straight) line R2-F, and elongated gap 123 is defined between back end line R1-B and front end line R2-F. The benefit of this arrangement is the provision that contact pad 122-8 does not extend behind first row R1, thereby facilitating a switch region 127 (indicated by shaded region) that is located behind first row R1 and adjacent to longer side edge 112. In effect, first group 122 and second group 124 are separated by an L-shaped region, which is formed by inter-row gap (first region) 123 extending between first row R1 and second row R2, and switch (second) region 127 extending from the back end of eighth contact pad 122-8 away from front edge 111 of PCB 110.

Referring to the left side of FIG. 1(A), according to another aspect, thirteenth contact pad 126 is substantially rectangular (approximately 5.4 mm by 1.3 mm), and has a front end that is located between front end R1-F and back end R1-B of first row R1, and a back end that is located between front end R2-F and back end R2-B of second row R2. As mentioned above, the main benefit of thirteenth contact pad 126 over contact pad C9 of MMC Specification Version 4.0 is reduced need for pad material and less opportunity for finger contact. Accordingly, in embodiments where this area reduction is not necessary, the larger, two-part contact pad C9 may be utilized in place of thirteenth contact pad 126.

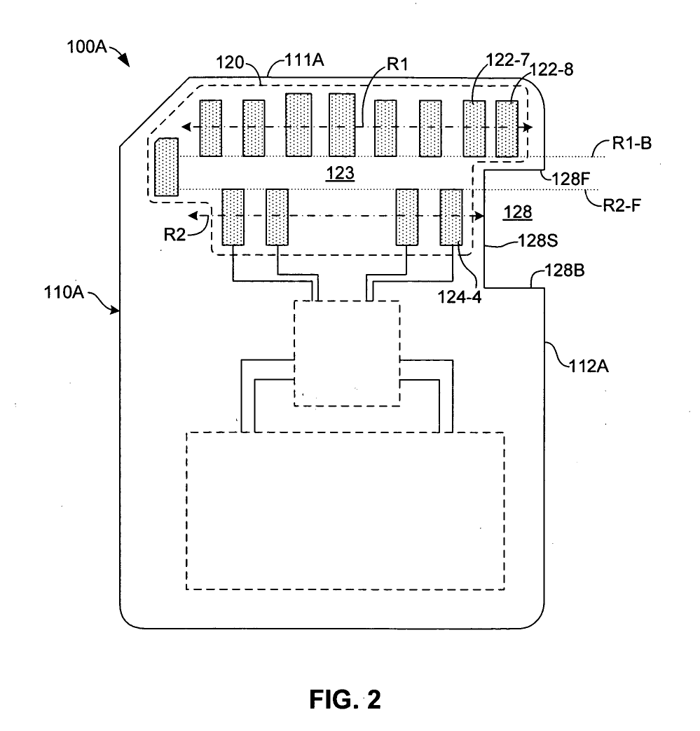

FIG. 2 is a plan view showing a PCBA 100A for a 13-pad memory card according to another embodiment of the present invention. PCBA 100A includes a PCB 110A having contact pad array 120 formed thereon in essentially the same manner as described above (i.e., such that elongated gap 123 is formed between first row R1 and second row R2). However, PCBA 100A differs from the embodiment described above in that a substantially rectangular alignment notch 128 is formed in longer side edge 112A of PCB 110A in the space corresponding to the switch region of the previous embodiment (i.e., in the region behind eighth contact pad 122-8). In one embodiment, notch 128 includes a front notch edge 128F and an opposing back notch edge 128B that extending substantially parallel to front edge 111A of PCB 110A, and a side notch edge 128S that extends parallel to longer side edge 112A. Front notch edge 128F is located between back end R1-B of first row R1 and front end R2-F of second row R2, and back notch edge 128B is located behind second row R2. Front notch edge 128F and back notch edge 128B have lengths selected such that at least a portion of eighth contact pad 122-8 is located between an area defined between the longitudinal extension of side notch edge 128S and longer side edge 112A. In one embodiment, front notch edge 128F and back notch edge 128B have lengths selected such that a portion of seventh contact pad 122-7 is located between an area defined between the longitudinal extensions of side notch edge 128S and longer side edge 112A. As described in additional detail below, alignment notch 128 facilitates precise positioning of PCBA 100A inside an SD-type housing, and also facilitates the addition of a write protect switch structure on the housing (not shown) subsequently mounted over PCBA 100A. Note that one or more additional alignment notches may be provided along either side edge 112A and 114A of PCB 110A.

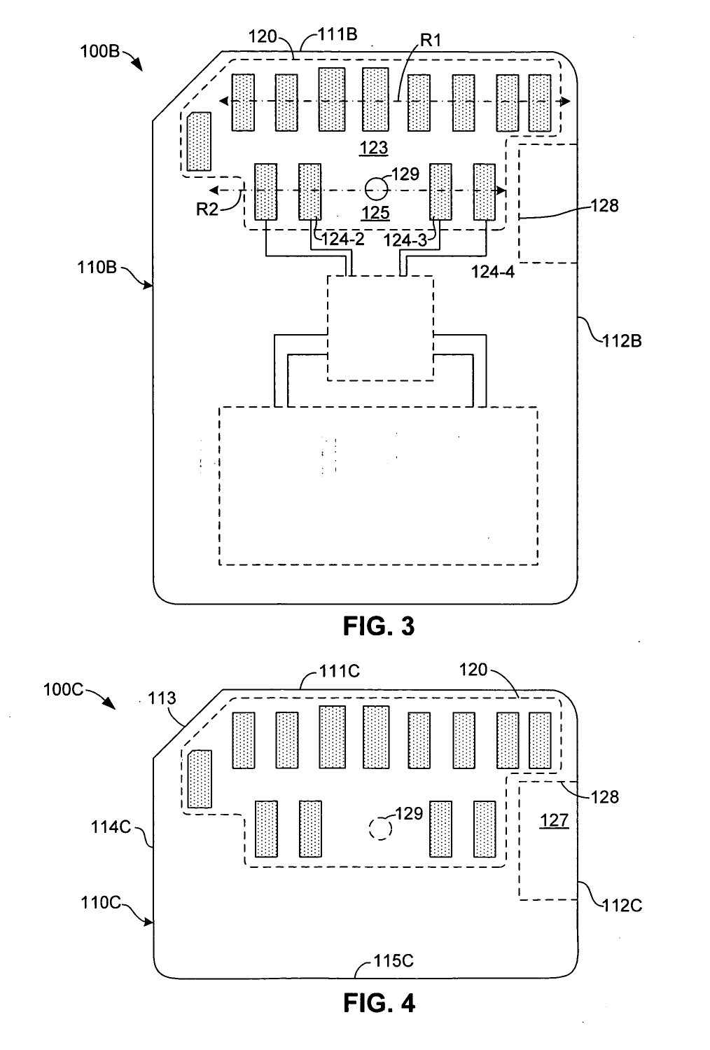

FIG. 3 is a plan view showing a PCBA 100B for a 13-pad memory card according to another embodiment of the present invention. PCBA 100B includes a PCB 110B having contact pad array 120 formed thereon in essentially the same manner as described above (i.e., such that elongated gap 123 is formed between first row R1 and second row R2, and central gap 125 is formed within the elongated gap 123 or in its vicinity). However, PCBA 100B differs from the embodiment described above in that at least one alignment hole 129 is formed through PCB 110B for purposes that will become clear below. In the disclosed embodiment, a single alignment hole 129 is provided in central gap 125 between contact pads 124-2 and 124-3 of second row R2. In other embodiment, alignment hole 129 may be positioned in another location, or more than one alignment holes may be provided. Referring to the right side of FIG. 3, in an alternative embodiment, alignment notch 128 (described above) may be utilized in addition to alignment hole 129 to further enhance the alignment of PCB 110B.

FIG. 4 is a plan view showing a PCBA 100C for a 13-pad memory card according to another embodiment of the present invention. PCBA 100C includes contact pad array 120, which is formed in essentially the same manner as described above, but PCB 110C is shortened according to another standard form factor established for MMC memory cards. In particular, PCB 110C has the same width (i.e., the distance between longer side edge 112C and shorter side edge 114C) as that described above, but a shortened card length (i.e., the distance between front edge 111C and back edge 115C) of about 18 mm. Note that PCBA 100C may include any of the switch region 127, alignment notch 128, and alignment hole 129, which are described above.

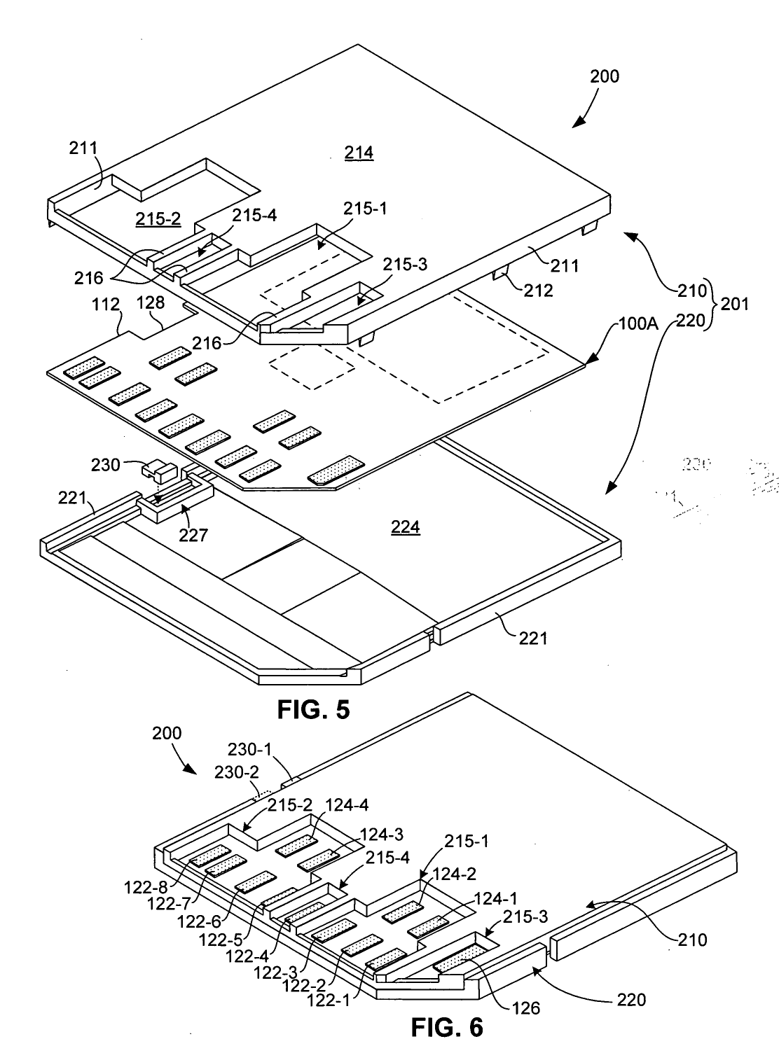

FIGS. 5 and 6 are exploded perspective and assembled perspective views, respectively, showing a memory card 200 including PCBA 100A (described above) and a two-part housing 201 including an upper cover 210 and a lower cover 220. In one embodiment, two-part housing 201 is constructed in accordance with the SD mechanical form factor, thereby providing a single structure for housing electronic components based on either the MMC or SD protocols, which in turn facilitates the production of integrated SD/MMC systems that operate on either protocol. Upper cover 210 includes a peripheral wall 211 having several connection structures (e.g., ultrasonic bonding structures) 212 extending downward from a lower edge thereof, and a planar upper wall 214 supported on peripheral wall 211. Similarly, lower cover 220 includes a peripheral wall 221 and a planar lower wall 224 supported on peripheral wall 221. The ultrasonic bonding structures 212 can optionally be constructed on the upper planar section of peripheral wall 211. When connected together, as indicated in FIG. 6, peripheral walls 211 of upper cover 210 are received inside peripheral walls 221 of lower cover 220, and connection structures 212 are melted to secure the two covers together. In an alternative embodiment (not shown) upper cover 210 may include a step-like geometry that extends over peripheral walls 221 of lower cover 220 (which are shorter in height), and the connection structures are located to secure the top edge of peripheral walls 221 to outer peripheral edges of upper cover 210.

According to an aspect of the invention, upper wall 214 of upper cover 210 defines several windows 215-1 through 215-4 that expose the contact pads formed on PCBA 10A, where at least one window exposes at least two contact pads from both the first and second rows of contact pads. Specifically, as indicated in FIG. 6, a first window 215-1 exposes contact pads 122-1 through 122-3 of the first row and contact pads 124-1 and 124-2 of the second row. Similarly, a second window 215-2 exposes contact pads 122-5 through 122-8 of the first row and contact pads 124-3 and 124-4 of the second row. In addition, cover 210 defines a third window 215-3 that exposes thirteenth contact pad 126, and a fourth window 215-4 that exposes contact pad 122-4. Note that several ribs 216 extend between the various windows and connect upper wall 214 to the front portion of the peripheral wall, thereby providing a rigid support for upper wall 214.

According to another aspect of the invention, lower cover 220 includes a mounting structure 227 for slidably receiving a write protect switch 230, which is mounted as indicated in FIG. 5 and held in place when upper cover 210 is secured to lower cover 220 as indicated in FIG. 6. Note that alignment notch 128 of PCBA 100A mounts tightly over mounting structure 227 during assembly, thereby self-aligning PCBA 100A to lower cover 220. Note also that write protect switch 230 at least partially extends into mounting structure 227 and alignment notch 128, and slides in a direction parallel to longer side edge 112 of PCBA 100A (shown in FIG. 5) between two write protect settings 230-1 and 230-2 (see FIG. 6) that are detected by a detection mechanism of a corresponding host socket (not shown).

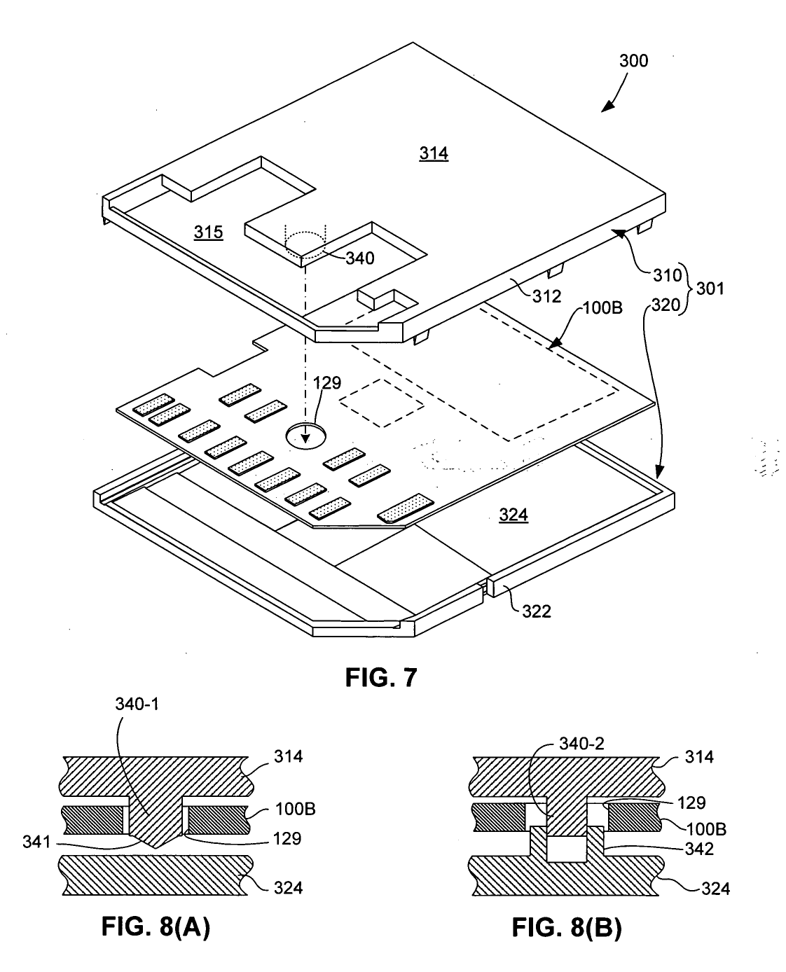

FIG. 7 is an exploded perspective view showing a memory card 300 including PCBA 100B (described above) and a two-part housing 301 including an upper cover 310 and a lower cover 320. Similar to housing 201 (described above), upper cover 310 includes a peripheral wall 312 and a planar upper wall 314 supported on peripheral wall 312, and lower cover 320 includes a peripheral wall 322 and a planar lower wall 324 supported on peripheral wall 322. Upper wall 314 defines a single window 315 that exposes all of the contact pads provided on PCB 110B. Upper cover 310 and lower cover 320 connect together in a manner similar to that described above, with the exception that upper cover 310 and/or lower cover 320 include an alignment pin 340 that extends through alignment hole 129 of PCBA 100B, thereby connecting upper wall 314 to lower body 324 to provide a rigid connection between upper cover 310 and lower cover 320. As indicated in FIG. 8(A), in one exemplary embodiment, an alignment pin 340-1 extends downward from upper wall 314 and is inserted through alignment hole 129 of PCBA 100B, and includes an ultrasonic bonding structure 341 that is secured to lower wall 324 during assembly. As indicated in FIG. 8(B), in another exemplary embodiment, an alignment pin 340-2 extends downward from upper wall 314, and lower wall 324 includes a receiving structure 342 that receives the lower end of alignment pin 340-2, which can then be secured by press-fit, adhesive, ultrasonic bonding, or another known mechanism. Note that one or more alignment features similar to 340 may be provided to assemblies illustrated in FIG. 5 or FIG. 7.

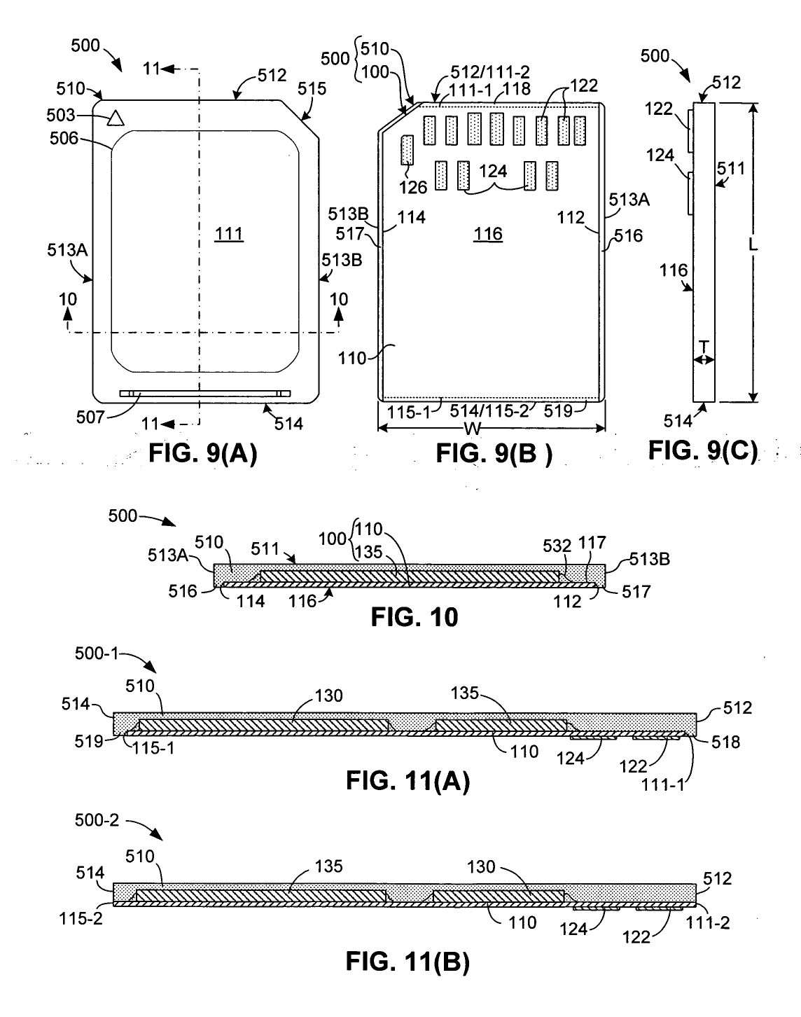

FIGS. 9(A), 9(B), and 9(C) are top, bottom, and side views, respectively, showing an MMC memory card 500 incorporating PCBA 100 (described above) and a single-piece housing meeting the MMC mechanical form factor in accordance with another exemplary specific embodiment of the present invention. Memory card 500 is also shown in cross-sectional view in FIG. 10, and in alternative embodiments in FIGS. 11(A) and 11(B).

Referring to FIG. 9(B), PCBA 100 is encased in molded outer casing 510 that forms a one piece housing over PCBA 100 such that lower surface 116 is partially exposed on the lower side of casing 510. As indicated in FIG. 9(A), casing 510 includes an upper surface 511, a front edge 512, side edges 513A and 513B, and a back edge 514. Casing 510 is substantially rectangular, except for a chamfer 515, which extends between front edge 512 and right side edge 513B, and matches the chamfered edge of PCB 110 (described above). Similar to all of the housing structures mentioned above, chamfer 515 facilitates correct insertion of memory card 500 into a card-hosting device by preventing insertion with the lower side facing upward (i.e., the card-hosting device is constructed such that the full insertion of memory card 500 requires the proper orientation of chamfer 515). In the left upper corner (FIG. 9(A)), a triangular insertion direction mark 503 is provided for indicating the proper card insertion direction, and an optional identification label 506 is affixed in a central region of the upper surface. An optional ridge 507 is provided adjacent to back edge 514 to facilitate manual insertion and removal of memory card 500 from a card-hosting device.

Referring again to FIG. 9(B), according to alternative embodiments described in more detail below, front edge 111 of PCB 110 is either offset from front edge 512 of casing 510 (indicated by dashed line 111-1), or is coincident with front edge 512 of casing 510 (indicated by reference numeral 111-2). Similarly, back edge 115 is either offset from back edge 514 (indicated by dashed line 115-1), or is coincident with back edge 514 of casing 510 (indicated by reference numeral 115-2). Side edges 112 and 114 of PCB 110 are offset from casing side edges 513A and 513B, respectively, and contact pads 122, 124 and 126 are exposed on lower surface 116 of substrate 110 and arranged adjacent to front edge 111.

FIG. 10 is a cross-sectional side view taken along section line 10-10 of FIG. 9(A). FIG. 10 shows molded casing 510 formed over PCBA 100, which includes substrate 110 and memory device 135 (e.g., a “Flash” memory chip) that is electrically connected to an upper surface 117 of substrate 110, e.g., by bonding wires 532. Because molding is more accurate and repeatable than the formation of substrate 110, memory card 500 provides a precise and reliable width dimension W and thickness dimension T (see FIGS. 9(B) and 9(C)) by accommodating slight variations in the width/height of substrate 110 and/or components 130 and 135. Further, by forming side portions 516 and 517 of casing 510 such that they extend over side edges 112 and 114 of substrate 110, respectively, memory card 500 provides a structure that resists damage due to delamination of substrate 110 from casing 510, and prevents exposure of substrate 110 to corrosive influences.

FIGS. 11(A) and 11(B) illustrate alternative cross-sectional views taken along section line 11-11 of FIG. 9(A). FIG. 11(A) shows a first memory card 500-1 formed in accordance with the first manufacturing method which provides end portions 518 and 519 of casing 510 that, similar to side portions 516 and 517 (discussed above), extend over and cover front edge 111-1 and back edge 115-1 of substrate 110, respectively. Although the length dimension L (see FIG. 9(C)) of memory card 500 is typically less critical than the width W and thickness T, the embodiment shown in FIG. 11(A) illustrates an embodiment in which the length dimension is accurately and repeatably generated, and provides the protective benefits discussed above. Alternatively, FIG. 11(B) illustrates a second memory card 500-2 formed in accordance with the second manufacturing method in which end portions are omitted, and where front edge 512 of casing 510 is coincident with front edge 111-2 of substrate 110 and back edge 514 of casing 510 is coincident with back edge 115-2 of substrate 110. Although the length dimension L (see FIG. 9(C)) of memory card 500-2 may be less accurate and repeatable than that of memory card 500-1, the associated manufacturing method facilitates the simultaneous molding of several memory cards, thereby potentially decreasing production costs.

The various embodiments of the structures and methods of this invention that are described above are illustrative only of the principles of this invention and are not intended to limit the scope of the invention to the particular embodiments described. Thus, the invention is limited only by the following claims and their equivalents.

1. A 13-pad memory card comprising:
a printed circuit board (PCB) including a front edge, a relatively long side edge, a relatively short side edge located opposite to the relatively long side edge, and a chamfer edge extending between front edge and the relatively short side edge; and
an array of metal contact pads formed on a first surface of the PCB, the array including:
a first group including eight substantially rectangular contact pads arranged in a first row, each contact pad of the first group having a front end located adjacent to the front edge of the PCB, a back end, and an elongated body extending between the front and back ends in a direction perpendicular to the front edge of the PCB, the first group including a first contact pad located at a first end of the first row adjacent to the chamfer edge, and an eighth contact pad located at a second end of the first row adjacent to the relatively long side edge, and
a second group including four substantially rectangular contact pads arranged in a second row that is parallel to the first row, each contact pad of the second group having a front end, a back end, and an elongated body extending between the front and back ends in a direction perpendicular to the front edge of the PCB, the second group including a ninth contact pad located at a first end of the second row adjacent to the chamfer edge, and a twelfth contact pad located at a second end of the second row adjacent to the relatively long side edge,
wherein the back ends of each contact pad of the first group define a first straight line,
wherein the front ends of each contact pad of the second group define a second straight line that is parallel to the first straight line, and
wherein an elongated gap is defined between the first and second straight lines.

2. The memory card according to claim 1, wherein a contact-free region is defined by the back end of the eighth contact pad, a side edge of the twelfth contact pad and the relatively long side edge of the PCB.

3. The memory card according to claim 1, wherein the contact pad array further comprises a thirteenth contact pad located between the first contact pad and the relatively short edge of the PCB, the thirteenth contact pad having a front end located adjacent to the chamfer edge.

4. The memory card according to claim 3, wherein the thirteenth contact pad comprises a substantially rectangular metal pad arranged such that the front end is located between the front and back ends of the contact pads of the first group, and a back end that aligned between the front and back ends of the contact pads of the second group.

5. The memory card according to claim 1, wherein the relatively long side edge of the PCB defines an alignment notch.

6. The memory card according to claim 5, wherein the alignment notch includes a front notch edge located between first and second straight lines, and a side notch edge that is parallel to the relatively long side edge and aligned such that at least a portion of the eighth contact pad is positioned between the side notch edge and the relatively long side edge.

7. The memory card according to claim 6,
wherein the first group includes a seventh contact pad located adjacent to the eighth contact pad, and
wherein the side notch edge is aligned with a portion of the seventh contact pad.

8. The memory card according to claim 1, wherein the PCB defines an alignment hole.

9. The memory card according to claim 8, wherein the second group further comprises a tenth contact pad and an eleventh contact pad, wherein a central gap is defined between the tenth and eleventh contact pads, and wherein the alignment hole is located in the central gap.

10. The memory card according to claim 1, further comprising a controller integrated circuit (IC) and a memory IC mounted on the PCB and electrically connected to at least one contact pad of the contact pad array.

11. The memory card according to claim 10, wherein the controller IC and the memory IC comprise MultiMediaCard (MMC) circuits.

12. The memory card according to claim 11, further comprising a two-part housing mounted over the PCB such that the array of contact pads are exposed through at least one window defined in the housing.

13. The memory card according to claim 12,
wherein the PCB defines an alignment hole, and
wherein the two-part housing includes an alignment pin extending through the alignment hole.

14. The memory card according to claim 12, further comprising a write protect switch movably connected to the two-part housing adjacent to the relatively long side edge of the PCB.

15. The memory card according to claim 12,
wherein the controller IC and the memory IC are mounted on a second surface of the PCB, the second surface being opposite to the first surface, and
wherein the memory card further comprises a casing molded over the controller IC and the memory IC.

16. The memory card according to claim 10, wherein the controller IC and the memory IC comprise Secure Digital (SD) circuits.

17. A 13-pad memory card comprising:
a printed circuit board (PCB) including a front edge, a relatively long side edge defining an alignment notch, a relatively short side edge located opposite to the relatively long side edge, and a chamfer edge extending between front edge and the relatively short side edge; and
an array of metal contact pads formed on a first surface of the PCB, the array including:
a first group including eight substantially rectangular contact pads arranged in a first row, each contact pad of the first group having a front end located adjacent to the front edge of the PCB, a back end, and an elongated body extending between the front and back ends in a direction perpendicular to the front edge of the PCB, the first group including a first contact pad located at a first end of the first row adjacent to the chamfer edge, and an eighth contact pad located at a second end of the first row adjacent to the relatively long side edge, and
a second group including four substantially rectangular contact pads arranged in a second row that is parallel to the first row, each contact pad of the second group having a front end, a back end, and an elongated body extending between the front and back ends in a direction perpendicular to the front edge of the PCB, the second group including a ninth contact pad located at a first end of the second row adjacent to the chamfer edge, and a twelfth contact pad located at a second end of the second row adjacent to the alignment notch,
wherein the alignment notch includes a front edge located between the front ends of the contact pads of the second group and the back end of the eighth contact pad of the first group, and a side notch edge that is parallel to the relatively long side edge and aligned such that at least a portion of the eighth contact pad is positioned between the side notch edge and the relatively long side edge.

18. The memory card according to claim 17,
wherein the first group includes a seventh contact pad located adjacent to the eighth contact pad, and
wherein the side notch edge is aligned such that at least a portion of the seventh contact pad is located between a longitudinal extension of the side notch edge and the longer side edge.

19. The memory card according to claim 18, further comprising:
a two-part housing mounted over the PCB such that the array of contact pads are exposed through at least one window defined in the housing, and
a write protect switch movably connected to the two-part housing such that a portion of the write protection switch is positioned inside the alignment notch.

20. The memory card according to claim 17, wherein the contact pad array further comprises a thirteenth contact pad located between the first contact pad and the relatively short edge of the PCB, the thirteenth contact pad having a front end located adjacent to the chamfer edge.

21. The memory card according to claim 20, wherein the thirteenth contact pad comprises a substantially rectangular metal pad arranged such that the front end is located between the front and back ends of the contact pads of the first group, and a back end that aligned between the front and back ends of the contact pads of the second group.

22. A 13-pad memory card comprising:
a printed circuit board (PCB) including a front edge, a relatively long side edge, a relatively short side edge located opposite to the relatively long side edge, and a chamfer edge extending between front edge and the relatively short side edge; and
an array of metal contact pads formed on a first surface of the PCB, the array including:
a first group including eight substantially rectangular contact pads arranged in a first row, each contact pad of the first group having a front end located adjacent to the front edge of the PCB, a back end, and an elongated body extending between the front and back ends in a direction perpendicular to the front edge of the PCB, the first group including a first contact pad located at a first end of the first row adjacent to the chamfer edge, and an eighth contact pad located at a second end of the first row adjacent to the relatively long side edge, and
a second group including four substantially rectangular contact pads arranged in a second row that is parallel to the first row, each contact pad of the second group having a front end, a back end, and an elongated body extending between the front and back ends in a direction perpendicular to the front edge of the PCB, the second group including a ninth contact pad and a tenth contact pad located at a first end of the second row adjacent to the chamfer edge, and an eleventh contact pad and a twelfth contact pad located at a second end of the second row adjacent to the relatively long side edge,
wherein a central gap is defined between the tenth and eleventh contact pads, and
wherein the PCB defines an alignment hole located in the central gap.

23. The memory card according to claim 22, further comprising a two-part housing mounted over the PCB such that the array of contact pads are exposed through at least one window defined in the housing, wherein the two-part housing includes an alignment pin extending through the alignment hole.
